(19) United States
(12) Patent Application Publication
(10) Pub. No.: US 2008/0309524 A1
(43) Pub. Date: Dec. 18, 2008

(54) Second-Order Polynomial, Interpolation-Based, Sampling Rate Converter and Method and Transmitters Employing the Same

(75) Inventors: Ioannis L. Syllaios, Richardson, TX (US); Khurram Waheed, Plano, TX (US); Robert B. Staszewski, Garland, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 12/121,090

(22) Filed: May 15, 2008

Related U.S. Application Data
(60) Provisional application No. 60/944,685, filed on Jun. 18, 2007.

(51) Int. Cl. H03M 7/00

(52) U.S. Cl. 341/61

(57) ABSTRACT

A sampling rate converter, a method of performing digital sampling rate conversion and a wireless transmitter incorporating the filter or the method. In one embodiment, the sampling rate converter includes: (1) an input configured to receive digital data from a first clock domain sampled at a first sampling rate, (2) an output configured to provide digital data to a second clock domain sampled at a second sampling rate that differs from the first sampling rate and (3) a filter with a second-order, polynomial-based impulse response coupled to the input and the output and configured to apply coefficients having only one nonunitary divisor to the digital data from the first clock domain.

### CROSS-REFERENCE TO PROVISIONAL APPLICATION

This application claims the benefit of U.S. Provisional Application Ser. No. 60/944,685, filed by Syllaios, et al., on Jun. 18, 2007, entitled “A Reduced Complexity Second-Order Polynomial Interpolation-Based Resampler with Filtering Performance Comparable to a Third-Order Polynomial Interpolation-Based Resampler,” commonly assigned with the invention and incorporated herein by reference.

### TECHNICAL FIELD OF THE INVENTION

The invention is directed, in general, to digital sampling and, more specifically, to a second-order polynomial, interpolation-based, digital sampling rate conversion (SRC) filter and method and transmitters employing the filter or the method.

### BACKGROUND OF THE INVENTION

An interpolative digital sampling rate conversion (SRC) filter (also called a “resampler”) is often required as an interface between two systems operating at asynchronous clock rates (constituting two clock domains). The purpose of the interpolative SRC filter is to receive data from the source system sampled at the source system's sampling rate, and transfer the data to the destination system sampled at the destination system's different sampling rate.

Designing an interpolative SRC filter for a particular application involves striking a balance between minimizing the amount of signal distortion (noise) that the SRC introduces and minimizing the hardware complexity or software overhead of the filter, as well as dissipated power. Often it is more important to minimize signal distortion than to minimize complexity or overhead, but the latter becomes particularly important in mobile (battery powered) radio frequency (RF) applications.

The resampling performance of the interpolative SRC filter hardware/software ultimately determines the digital noise floor of the data at the resampled clock domain (i.e., at the output of the interpolative SRC filter). However, the asynchronous relationship between the two clock domains, the ratio between the SRC input-output clock frequencies, the bit-width of the data stream and the relative bandwidth of the signal being resampled affect that resampling performance.

The requirements of a particular application determine the acceptable digital noise floor in resampling applications, which in turn dictates the selection of the resampling technique. One example of an application for an interpolative SRC filter is in the transmitter of a Wideband Code-Division Multiple Access (WCDMA) wireless device, where the interpolative SRC filter may be employed in lieu of a surface acoustic wave (SAW) or bulk-acoustic wave (BAW) inter-stage filter between a radio-frequency integrated circuit (RFIC) and a power amplifier (PA). SAW and BAW filters typically cannot be integrated with other circuitry, which increases the device's overall size and part-count. SAW and BAW filters are also relatively expensive, which increases the device's cost. A conventional second-order (Gardner or Farrow) SRC filter, while size-, cost- and power-efficient, produces far more noise than WCMDA can tolerate. The noise floor requirements are such that only a third-order (Lagrange) interpolative SRC filter or higher-order filter operating at a clock frequency of more than 200 MHz has proven adequate. Third-order interpolative digital resampling at such a high clock rate is costly due to increased hardware complexity and power consumption.

### SUMMARY OF THE INVENTION

To address the above-discussed deficiencies of the prior art, one aspect of the invention provides a sampling rate converter. In one embodiment, the sampling rate converter includes: (1) an input configured to receive digital data from a first clock domain sampled at a first sampling rate, (2) an output configured to provide digital data to a second clock domain sampled at a second sampling rate that differs from the first sampling rate and (3) a filter with a second-order, polynomial-based impulse response coupled to the input and the output and configured to apply coefficients having only one nonunitary divisor to the digital data from the first clock domain.

Another aspect of the invention provides a method of performing digital sampling rate conversion. In one embodiment, the method includes: (1) receiving digital data from a first clock domain sampled at a first sampling rate and (2) employing a filter with a second-order, polynomial-based impulse response to apply coefficients having only one nonunitary divisor to the digital data from the first clock domain, thereby to provide digital data to a second clock domain sampled at a second sampling rate that differs from the first sampling rate.

Another aspect of the invention provides a wireless transmitter. In one embodiment, the wireless transmitter includes: (1) a digital baseband unit, (2) a pulse-shaping filter coupled to the digital baseband unit and configured to operate in a first clock domain to provide digital data sampled at a first sampling rate, (3) a sample rate converter including a filter with a second-order, polynomial-based impulse response coupled to the pulse-shaping filter and responsive to an interpolating signal to apply coefficients having only one nonunitary divisor to the digital data from the first clock domain and (4) an output coupled to the sample rate converter and configured to provide digital data to a second clock domain sampled at a second sampling rate that differs from the first sampling rate.

### BRIEF DESCRIPTION OF THE DRAWINGS

For a more complete understanding of the invention, reference is now made to the following descriptions taken in conjunction with the accompanying drawings, in which:

FIG. 1A is a block diagram illustrating an interpolative SRC filter spanning two systems and two respective clock domains;

FIG. 1B is a plot illustrating interpolation between two clock domains as the interpolative SRC filter of FIG. 1A may carry out;

FIG. 2 is a schematic diagram of one embodiment of an interpolative SRC filter constructed according to the principles of the invention;

FIG. 3 is a schematic diagram of one embodiment of a circuit for generating various clock signals to be provided to the interpolative SRC filter of FIG. 2;

FIG. 4 is a plot comparing a frequency response of one embodiment of an interpolative SRC filter constructed according to the principles of the invention to those of a poorer-performing second-order (Gardner or Farrow) interpolative SRC filter and a more complex third-order (Lagrange) interpolative SRC filter;

FIG. 5 is a plot comparing an RF power spectrum (offset from the carrier) of one embodiment of an interpolative SRC filter constructed according to the principles of the invention to those of a poorer-performing second-order (Gardner or Farrow) interpolative SRC filter and a more complex third-order (Lagrange) interpolative SRC filter;

FIG. 6 is a block diagram of one embodiment of a polar wireless transmitter having one clock source and containing one embodiment of an interpolative SRC filter constructed according to the principles of the invention in its digital signal processing path;

FIG. 7 is a block diagram of one embodiment of a Cartesian wireless transmitter having one clock source and containing one embodiment of an interpolative SRC filter constructed according to the principles of the invention in its digital signal processing path; and

FIG. 8 is a flow diagram of one embodiment of a method of second-order polynomial, interpolation-based, digital sampling rate conversion carried out according to the principles of the invention.

### DETAILED DESCRIPTION

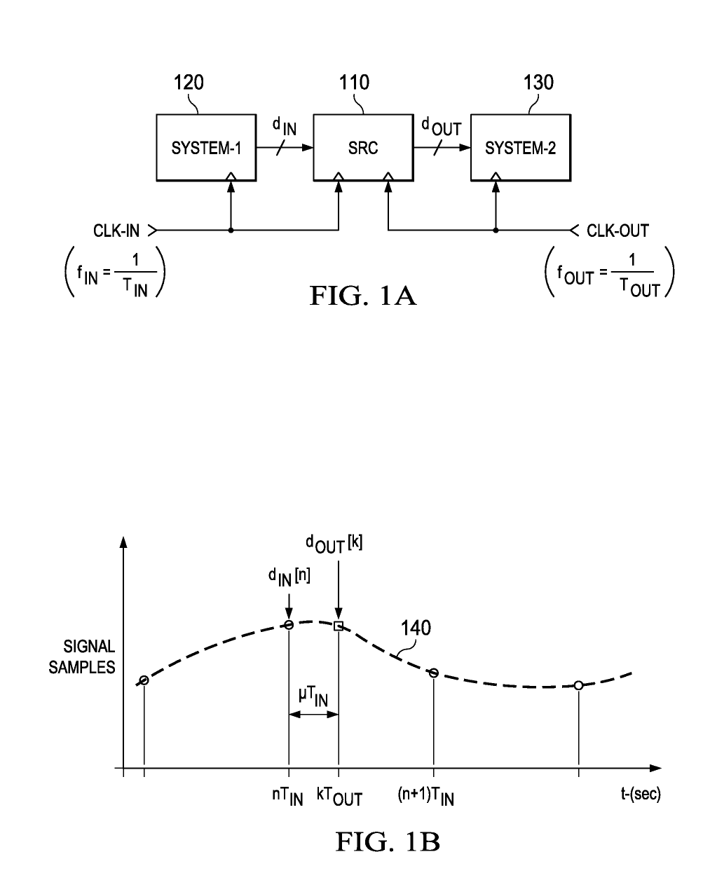

FIG. 1A is a block diagram illustrating an interpolative SRC filter 110 spanning two systems, System-1 120 and System-2 130, and two respective clock domains, those of CLK-IN and CLK-OUT, respectively. The frequency of CLK-IN is designated f_{IN}, and is, of course, the reciprocal of the period of CLK-IN, which is designated T_{IN}. Likewise, the frequency of CLK-OUT is designated f_{OUT}, and is, of course, the reciprocal of the period of CLK-OUT, which is designated T_{OUT}. In the discussion that follows, d_{IN} or x is used to designate a sample taken in the CLK-IN clock domain at clock cycle n (i.e., at time nT_{IN}), and d_{OUT} or y is used to designate a sample of data d taken in the CLK-IN clock domain at clock cycle k (i.e., at time kT_{OUT}). The interpolative SRC filter 110 is configured to receive digital data from the System-1 120 sampled at a sampling rate set by CLK-IN, resample that digital data at a sampling rate set by CLK-OUT and provide that resampled digital data to the System-2 130. Thus, the interpolative SRC filter 110 is tasked to convert x[n]-type samples to y[k]-type samples without creating more noise than a particular application tolerates.

FIG. 1B is a plot illustrating interpolation between the CLK-IN and CLK-OUT clock domains as the interpolative SRC filter 110 may carry out. Taken together, digital samples d_{IN}[n] taken in the CLK-IN clock domain describe a continuous-time signal 140. In the example of FIG. 1B, the interpolative SRC filter 110 is to convert two successive CLK-IN clock domain samples nT_{IN} and (n+1)T_{IN} into one CLK-OUT clock domain sample kT_{OUT}. FIG. 1B shows that kT_{OUT} lies between, but off-center with respect to, nT_{IN} and (n+1)T_{IN}. The time displacement between nT_{IN} and kT_{OUT} may be expressed in terms of a third, interpolating signal mu (μ), the time displacement between NT_{IN} and kT_{OUT} therefore being μT_{IN}.

The interpolating signal, μ, therefore represents the difference between CLK-IN and CLK-OUT pulses and thus determines how adjacent samples from one clock domain are interpolated to yield a sample in the other clock domain. In the illustrated embodiment, μ is derived by determining on a continual basis the time difference that separates a most-recent CLK-IN pulse from a most-recent CLK-OUT pulse. Unless the frequencies of CLK-IN and CLK-OUT (e.g., CLK-IN and CLK-OUT may be asynchronous) are related by an integer multiple, μ varies over time. Either rising or falling edges of the pulses may be used to determine the difference, depending upon how the samples are edge-triggered.

As described above, many high-speed applications for interpolative SRC filters, such as WCDMA transmitters, require third-order interpolative SRC (Lagrange) filters to meet noise floor requirements. Conventional second-order interpolative SRC (Gardner or Farrow) filters are inadequate.

Equation (1), below, gives an example of a typical third-order interpolative SRC filter:

$$y [ k ] = \{ \frac{1}{6} \cdot x [ n ] - \frac{1}{2} \cdot x [ n - 1 ] + \frac{1}{2} \cdot x [ n - 2 ] - \frac{1}{6} \cdot x [ n - 3 ] \} \cdot {μ}^{3} + \{ \frac{1}{2} \cdot x [ n - 1 ] - x [ n - 2 ] + \frac{1}{2} \cdot x [ n - 3 ] \} \cdot {μ}^{2} + \{ - \frac{1}{6} \cdot x [ n ] + x [ n - 1 ] - \frac{1}{2} \cdot x [ n - 2 ] - \frac{1}{3} \cdot x [ n - 3 ] \} \cdot μ + x [ n - 2 ] . \qquad ( 1 )$$

The third-order nature of Equation (1) is apparent in the existence of its μ³ term. Equation (1) further applies nonunitary coefficients having three different nonunitary (i.e., non-1) coefficient divisors (i.e., 6, 3 and 2) to the samples from the CLK-IN clock domain.

Table 1, below, sets forth the hardware components required by a hardware implementation of the third-order interpolative SRC filter described by Equation (1).

TABLE 1
Components Required by Typical
Third-Order Interpolative SRC Filter

| | Required by |
|---|---|
| Component | Third-Order Filter |
| Adder | 8 (Low rate) |
| | 3 (High rate) |
| Multiplier | 1 (Low rate) |
| | 3 (High rate) |
| Shift Operator | 1 (Low rate) |
| Delay Element | 9 (Low rate) |

The existence of the third-order term and the three different nonunitary coefficient divisors of Equation (1) cause the component count to be as large as Table 1 indicates. A software implementation of the third-order interpolative SRC filter described by Equation (1) would require a relatively large number of more complex instructions and therefore a more powerful processor, a higher processor clock rate or both.

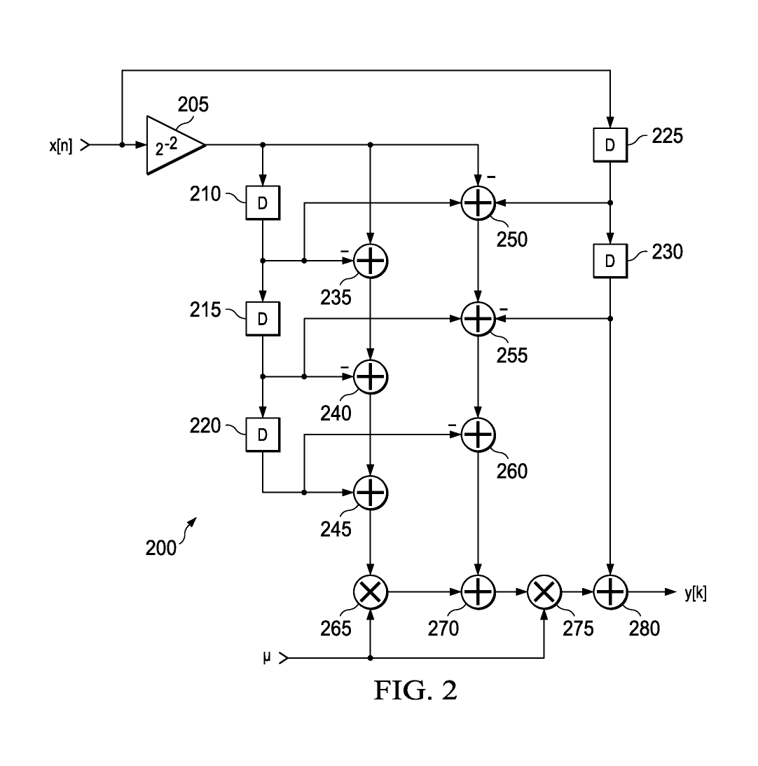

FIG. 2 is a schematic diagram of one embodiment of an interpolative SRC filter 200 constructed according to the principles of the invention. The interpolative SRC filter 200 has a second-order, polynomial-based impulse response and performs Equation (2), below:

$$y [ k ] = \{ \frac{1}{4} \cdot x [ n ] - \frac{1}{4} \cdot x [ n - 1 ] - \frac{1}{4} \cdot x [ n - 2 ] + \frac{1}{4} \cdot x [ n - 3 ] \} \cdot {μ}^{2} + \{ - \frac{1}{4} \cdot x [ n ] + \frac{5}{4} x [ n - 1 ] - \frac{3}{4} \cdot x [ n - 2 ] - \frac{1}{4} \cdot x [ n - 3 ] \} \cdot μ + x [ n - 2 ] . \qquad ( 2 )$$

Equation (2) has, at most, a second-order term (μ²). Equation (2) also applies coefficients having only one nonunitary divisor (i.e., 4) to the samples from the CLK-IN clock domain. As a result, the interpolative SRC filter 200 requires fewer components than did the typical third-order interpolative SRC filter described above, as will now be shown to be the case.

For purposes of FIG. 2, it will be assumed that the frequency of CLK-IN has a lower rate than that of CLK-OUT. Therefore, components in the interpolative SRC filter 200 that are driven by CLK-IN are designated as low-rate, and components that are driven by CLK-OUT are designated as high-rate. However, those skilled in the pertinent art should understand that the invention is not limited to particular values of or relationships between the frequencies of CLK-IN and CLK-OUT and that, indeed, the frequency of CLK-IN could be greater than that of CLK-OUT.

Input data samples x[n] (i.e., d_{IN}[n]) are received into the interpolative SRC filter 200 as shown. A low-rate shift operator 205 receives x[n] and divides their values by four to yield ¼·x[n]. Cascaded delay elements 210, 215, 220, receive the shifted x[n] and delay them by one clock cycle per element (i.e., n−1, n−2, n−3) to yield ¼·x[n−1], ¼·x[n−2], ¼·x[n−3]. Cascaded delay elements 225, 230 also receive (unshifted) x[n] and delay them by one clock cycle per element to yield x[n−1], x[n−2], x[n−3].

A low-rate adder 235 receives ¼·x[n] from the shift operator 205 and ¼·x[n−1] from the delay element 210 and subtracts the latter from the former to yield ¼·x[n−1], ¼·x[n−1]. A low-rate adder 240 receives ¼·x[n−2] from the delay element 215 and ¼·x[n]−¼·x[n−1] from the adder 235 and subtracts the latter from the former to yield ¼·x[n]−/−x[n−1]−/−x[n−2]. A low-rate adder 245 receives ¼·x[n−3] from the delay element 220 and ¼·x[n]−¼·x[n−1]−¼·x[n−2] from the adder 240 and adds the two to yield ¼·x[n]−¼·x[n−1]−¼·x[n−2]+¼·x[n−3], to which μ² will be applied.

A low-rate adder 250 receives ¼·x[n−1] from the delay element 210, x[n−1] from the delay element 225 and ¼·x[n] from the delay element 210 and subtracts the latter from the sum of the two former to yield ¼·x[n]+ 5/4·x[n−1]. A low-rate adder 255 receives ¼·x[n−2] from the delay element 215, x[n−2] from the delay element 230 and −¼·x[n]+ 5/4·x[n−1] from the adder 250 and subtracts the latter from the sum of the two former to yield −¼·x[n]+ 5/4·[n−1]−¾·x[n−2]. A low-rate adder 260 receives −¼·x[n]+ 5/4·x[n−1]−¾·x[n−2] from the adder 255 and ¼·x[n−3] from the delay element 220 and subtracts the latter from the former to yield −¼·x[n]+ 5/4·x[n−1]−¾·x[n−2]−¼·x[n−3], to which μ will later be applied.

A high rate multiplier 265 receives ¼·x[n]−¼·x[n−1]¼·x[n−2]+¼·x[n−3] from the adder 245, multiplying it by μ² to yield {¼·x[n]−¼·x[n−1]−¼·x[n−2]+¼·x[n−3]}·μ². A high rate multiplier 270 receives −¼·x[n]+ 5/4·x[n−1]¾·x[n−2]−¼·x[n−3] from the adder 260, multiplying it by μ to yield {−¼·x[n]+ 5/4·x[n−1]−¾·x[n−2]−¼·x[n−3]}·μ. A high rate adder 275 receives {¼·x[n]−¼·x[n−1]−¼·x[n−2]+¼·x[n−3]}·μ² from the multiplier 265 and ¼·x[n]+ 5/4·x[n−1]−¾·x[n−2]−¼·x[n−3]}·μ from the multiplier 270, adding the two to yield {¼·x[n]−¼·x[n−1]¼·x[n−2]+¼·x[n−3]}·μ²+¼·x[n]+ 5/4·x[n−1]−¼·x[n−2]−¼·x[n−3]}·μ. A final high rate adder 280 receives {¼·x[n]−¼·x[n−1]¼·x[n−2]+¼·x[n−3]}·μ²+¼·x[n]+ 5/4·x[n−1]−¾·x[n−2]−¼·x[n−3]}·μ from the adder 275 and x[n−2] from the delay element 230, adding the two to yield {¼·x[n]−¼·x[n−1]−¼·x[n−2]+¼·x[n−3]}·μ²+¼·x[n]+ 5/4·x[n−1]−¾·x[n−2]−¼·x[n−3]}·μ+x[n−2], which is provided as output samples y[k] (i.e., d_{OUT} [n]). Equation (2) is therefore carried out.

Table 2, below, sets forth the hardware components required by the interpolative SRC filter 200.

TABLE 2
Components Required by the Second-Order
Interpolative SRC Filter of FIG. 2

| | Required by Illustrated |
|---|---|
| | Embodiment of |
| Component | Second-Order Filter |
| Adder | 6 (Low rate) |
| | 2 (High rate) |
| Multiplier | 2 (High rate) |
| Shift Operator | 1 (Low rate) |
| Delay Element | 5 (Low rate) |

Comparing Table 2 to Table 1 reveals a substantial reduction in component count. A software embodiment of the second-order interpolative SRC filter 200 requires a smaller number of more complex instructions and therefore a less powerful processor, a lower processor clock rate or both, as well as lower consumed power, than the typical third-order interpolative SRC filter described above.

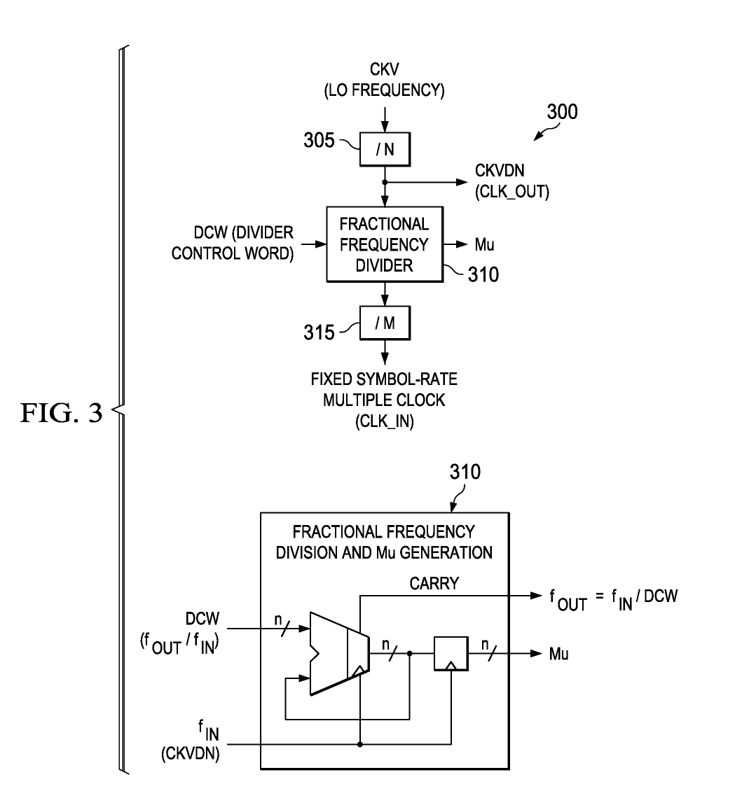

Having described an example of a second-order interpolative SRC filter, an example of a circuit capable of generating μ will now be described. FIG. 3 is a block and schematic diagram of one embodiment of a clock generating circuit 300 for generating clock signals, including μ. The clock generating circuit 300 in an RF transmission system generates the fixed clocks that are multiples of the baseband symbol rate clock. The circuit 300 receives an input clock signal, which may be a local oscillator (LO) clock signal CKV. A frequency divider 305 (implemented, for example, as a clock edge divider) divides CKV by a constant, N (typically an integer), to produce a downconverted clock signal CKVDN, which becomes CLK-OUT, the clock signal of the domain that receives the output samples y[k] or d_{OUT} of the interpolative SRC filter 200. A fractional frequency divider 310 produces μ, the interpolating signal provided to the interpolative SRC filter 200. A frequency divider 315 divides CKVDN by a constant, M (typically an integer, which could be unity), to produce a fixed symbol-rate multiple clock signal CLK-IN, which becomes the clock signal of the domain that provides the input samples x[n] or d_{IN} to the interpolative SRC filter 200.

μ numerically represents the relative location of the CLK_OUT clock edges and the fixed-frequency clock (CLK_IN) edges in a normalized domain. The SRC employs μ to perform the sampling rate conversion between the two clock domains.

A divider control word (DCW) is the ratio of the output and input frequencies. In the illustrated embodiment, the DCW is computed at the LO frequency and is provided to, and accumulated in, the fractional frequency divider 310. In the illustrated embodiment, the DCW is accumulated on input clock (CKVDN) edges. The DCW (which may be normalized such that 0≦DCW<1) is represented by an n-bit unsigned fixed-point number. The output range of the accumulator is digitally normalized to be in the range of zero to one. In the illustrated embodiment, a carry bit is set high when the accumulated value exceeds “1.” The fractional frequency divider 310 thus produces an output frequency having an average frequency equal to the desired output frequency (f_{OUT}=f_{IN}/DCW). The carry output is used as the output clock of the fractional frequency divider 310. The input clock (f_{IN}) resamples the n-bit accumulator output to generate μ.

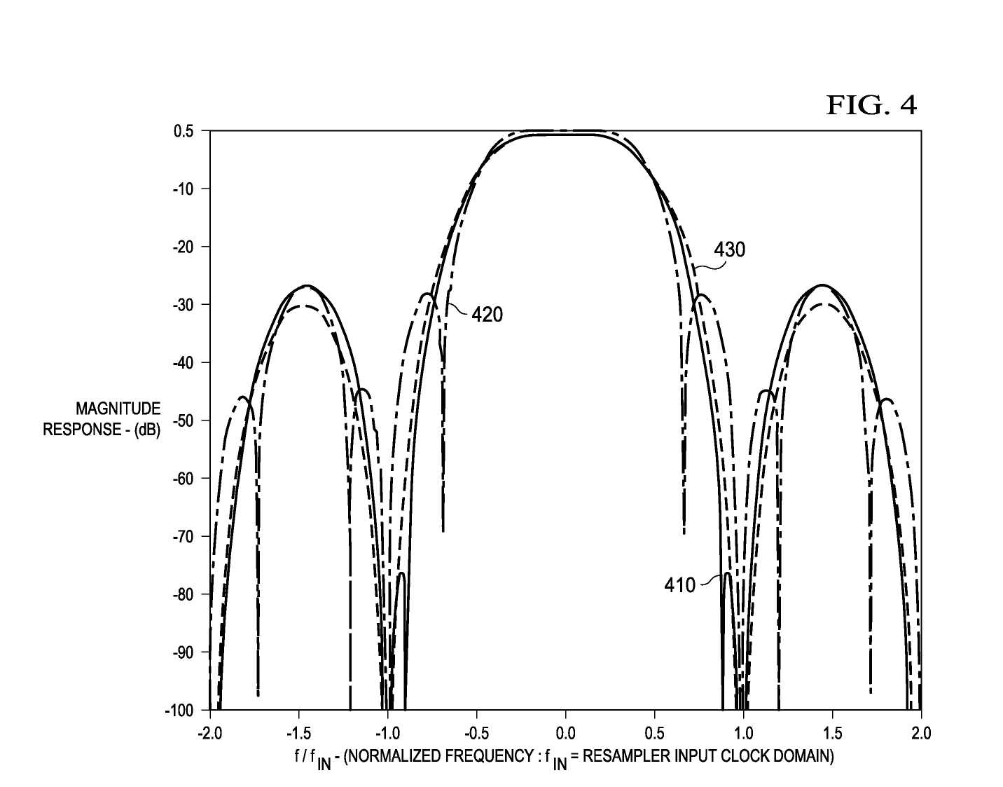

The interpolative SRC filter 200 achieves substantially the same performance of the third-order polynomial interpolative SRC filter without its attendant size, component-count, power consumption and cost disadvantages. FIG. 4 shows this graphically. FIG. 4 is a plot comparing a frequency response of one embodiment of an interpolative SRC filter constructed according to the principles of the invention (represented by a solid curve 410) to those of a poorer-performing second-order (Gardner or Farrow) interpolative SRC filter (represented by a curve 420) and a more complex third-order (Lagrange) interpolative SRC filter (represented by a curve 430). It should be noted that the curve 410 correlates closely to the curve 430. In contrast, the curve 420 contains significant sidelobes that produce noise.

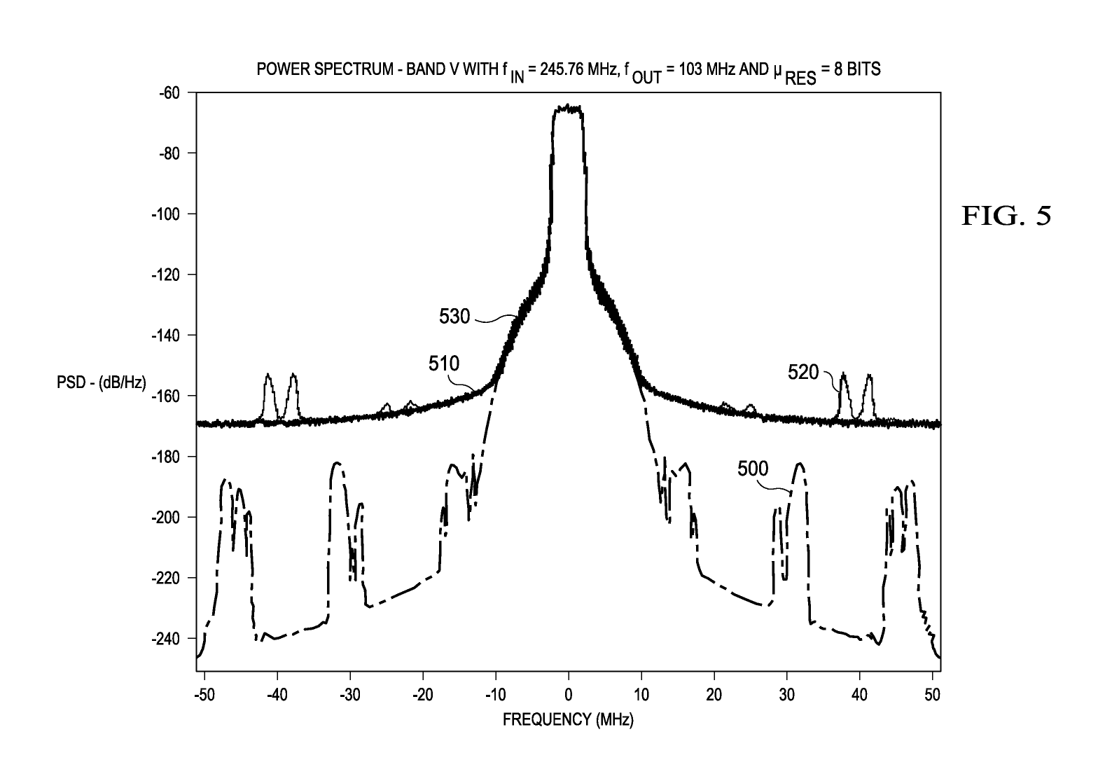

FIG. 5 is a plot comparing a power spectrum of one embodiment of an interpolative SRC filter constructed according to the principles of the invention (represented by a curve 510) to those of a poorer-performing second-order (Gardner or Farrow) interpolative SRC filter (represented by a curve 520) and a more complex third-order (Lagrange) interpolative SRC filter (represented by a curve 530). Source data (WCDMA) is plotted in a curve 500 for comparison. The source data shown in the curve 500 is in floating point form to highlight the low-amplitude signal replicas in the data which are amplified to an unacceptable level by the second-order (Gardner or Farrow) interpolative SRC filter of the curve 520. In contrast, the curves 510, 530 correlate closely.

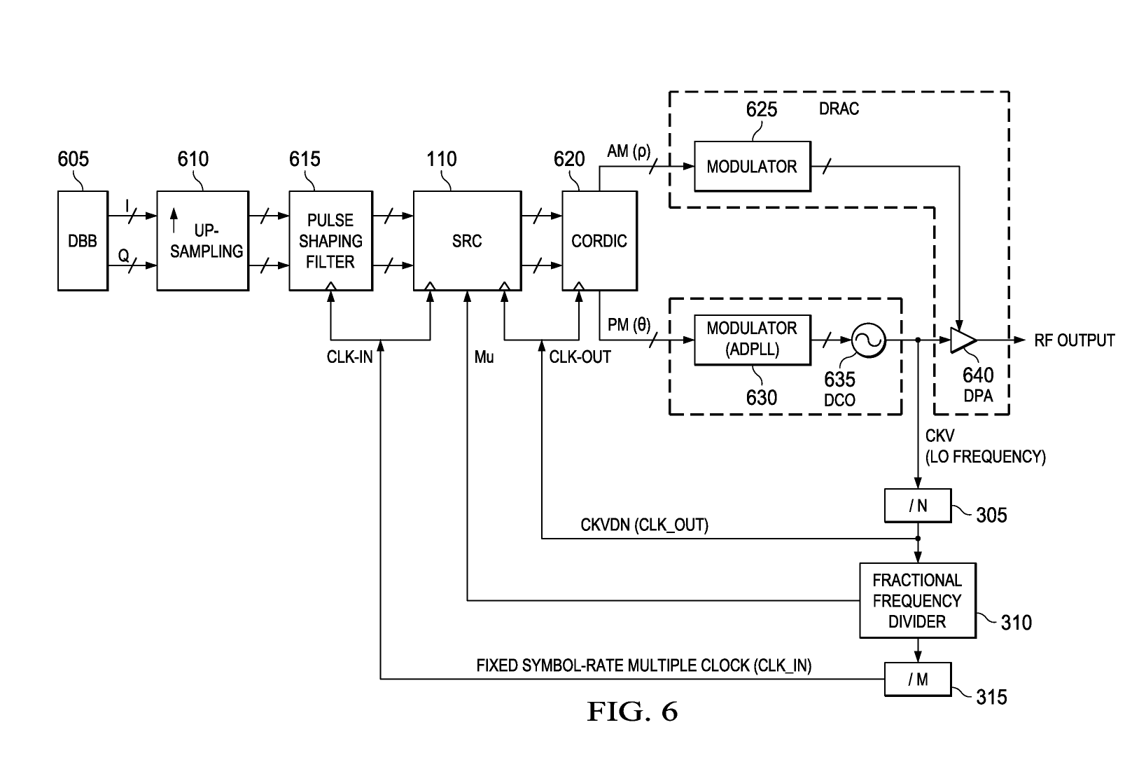

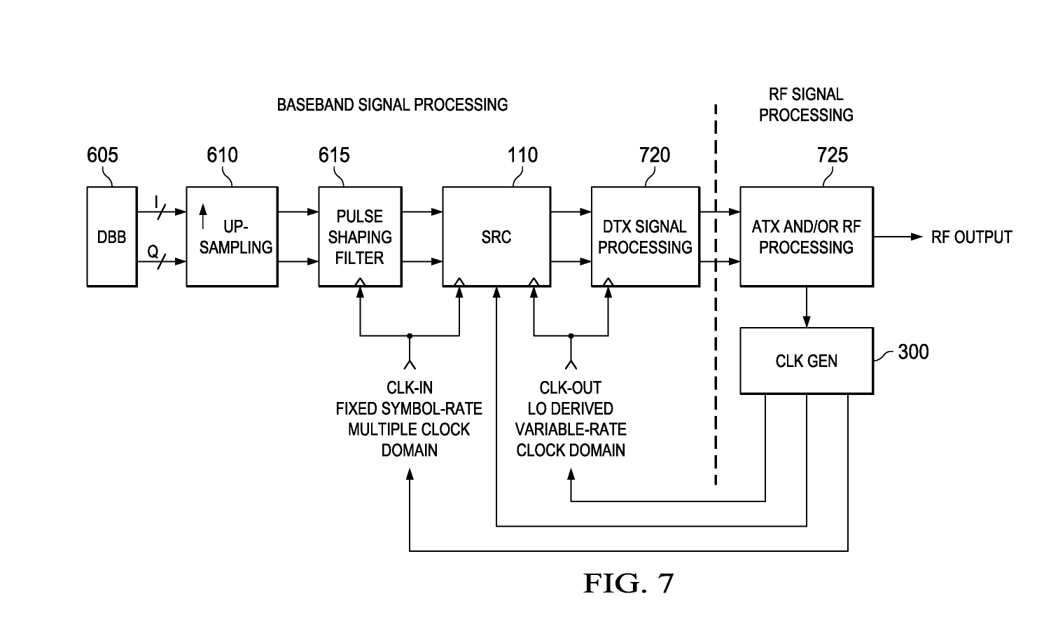

As described above, the interpolative SRC filter constructed according to the principles of the invention has many applications. FIGS. 6 and 7 show two such applications.

FIG. 6 is a block diagram of one embodiment of a polar wireless transmitter having one clock source and containing one embodiment of an interpolative SRC filter constructed according to the principles of the invention in its digital signal processing path. The polar transmitter receives quadrature baseband signals I, Q from a digital baseband unit 605. The quadrature baseband signals are upsampled in an upsampler 610. A pulse-shaping filter 615, which is part of the CLK-IN clock domain, shapes the upsampled quadrature baseband signals to comply with wireless standards. The interpolating SRC filter, which contains an instance of the interpolating SRC filter 200 for each quadrature baseband signal I and Q, is driven by CLK-IN, μ and CLK-OUT and resamples the quadrature baseband signals for the CLK-OUT clock domain. A COordinate Rotation DIgital Computer (CORDIC) unit 620 receives and rotates the resampled quadrature baseband signals to yield amplitude- and phase-modulation components ρ, θ. A modulator 625 receives and amplitude modulates the amplitude-modulation component ρ. An all-digital phase-locked loop (ADPLL) modulator 630 receives and phase-modulates the phase-modulation component θ. A digitally controlled oscillator (DCO) 635 oscillates as a function of the phase of the ADPLL 630, yielding a phase-modulated LO clock signal. The LO clock signal is received by the frequency divider 305 and a digital power amplifier (DPA) 640, which modulates LO using the output of the modulator 625, yielding an RF output as shown. The modulator 625 and DPA 640 may be together regarded as a digital-to-RF amplitude converter (DRAC). It should be noted that the CLK-OUT clock likely contains a frequency modulation component, which normally is not significant to affect system operation. For wireless standards with wider modulation bandwidths, however, the modulation frequency or timing deviation can be removed through fractional division or compensated through interpolation, since the frequency modulation is known precisely. In this case, the undesired timing deviation of the clocks due to the modulation can adjust the value of μ.

FIG. 7 is a block diagram of one embodiment of a Cartesian wireless transmitter having one clock source and containing one embodiment of an interpolative SRC filter constructed according to the principles of the invention in its digital signal processing path. The Cartesian transmitter receives quadrature baseband signals I, Q from the digital baseband unit 605. The quadrature baseband signals are upsampled in the upsampler 610. The pulse-shaping filter 615, which is part of the CLK-IN clock domain, shapes the upsampled quadrature baseband signals. The interpolating SRC filter, which contains an instance of the interpolating SRC filter 200 for each quadrature baseband signal I and Q, is driven by CLK-IN, μ and CLK-OUT and resamples the quadrature baseband signals for the CLK-OUT clock domain. A digital transmitter (DTX) signal processor 720 receives the resampled quadrature baseband signals, providing them to an analog transmitter (ATX) and/or RF processor 725 as shown, which produces the LO clock signal and an RF output as shown. The LO clock signal is provided to the clock generating circuit 300, which provides CLK-IN, μ and CLK-OUT as shown.

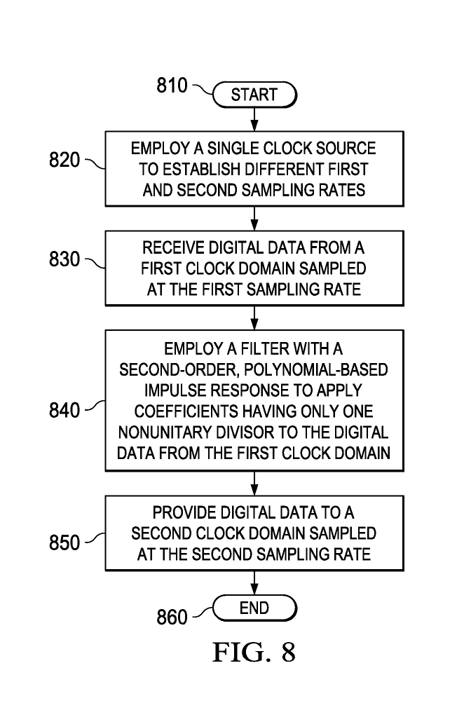

FIG. 8 is a flow diagram of one embodiment of a method of second-order polynomial, interpolation-based, digital sampling rate conversion carried out according to the principles of the invention. The method begins in a start step 810. In a step 820, a single clock source is employed to establish different first and second sampling rates. In a step 830, digital data is received from a first clock domain sampled at the first sampling rate. In a step 840, a filter with a second-order, polynomial-based impulse response is employed to apply coefficients having only one nonunitary divisor to the digital data from the first clock domain. In a step 850, digital data is provided to a second clock domain sampled at a second sampling rate that differs from the first sampling rate. The method ends in an end step 860.

Those skilled in the art to which the invention relates will appreciate that other and further additions, deletions, substitutions and modifications may be made to the described embodiments without departing from the scope of the invention.

What is claimed is:

1. A sampling rate converter, comprising:
an input configured to receive digital data from a first clock domain sampled at a first sampling rate;
an output configured to provide digital data to a second clock domain sampled at a second sampling rate that differs from said first sampling rate; and
a filter with a second-order, polynomial-based impulse response coupled to said input and said output and configured to apply coefficients having only one nonunitary divisor to said digital data from said first clock domain.

2. The sampling rate converter as recited in claim 1 wherein said nonunitary divisor is four.

3. The sampling rate converter as recited in claim 1 wherein a single clock source is employed to establish said first sampling rate and said second sampling rate.

4. The sampling rate converter as recited in claim 1 wherein said first sampling rate is less than said second sampling rate.

5. The sampling rate converter as recited in claim 1 wherein said filter is further configured to perform:
$$y [ k ] = \{ \frac{1}{4} \cdot x [ n ] - \frac{1}{4} \cdot x [ n - 1 ] - \frac{1}{4} \cdot x [ n - 2 ] + \frac{1}{4} \cdot x [ n - 3 ] \} \cdot {μ}^{2} + \{ - \frac{1}{4} \cdot x [ n ] + \frac{5}{4} x [ n - 1 ] - \frac{3}{4} \cdot x [ n - 2 ] - \frac{1}{4} \cdot x [ n - 3 ] \} \cdot μ + x [ n - 2 ] .$$

6. The sampling rate converter as recited in claim 1 wherein said first sampling rate and said second sampling rate are not related by an integer multiple.

7. The sampling rate converter as recited in claim 1 wherein said sampling rate converter is employed in a wireless transmitter selected from the group consisting of:
a polar transmitter, and
a Cartesian transmitter.

8. A method of performing digital sampling rate conversion, comprising:
receiving digital data from a first clock domain sampled at a first sampling rate; and
employing a filter with a second-order, polynomial-based impulse response to apply coefficients having only one nonunitary divisor to said digital data from said first clock domain, thereby to provide digital data to a second clock domain sampled at a second sampling rate that differs from said first sampling rate.

9. The method as recited in claim 8 wherein said nonunitary divisor is four.

10. The method as recited in claim 8 further comprising employing a single clock source to establish said first sampling rate and said second sampling rate.

11. The method as recited in claim 8 wherein said first sampling rate is less than said second sampling rate.

12. The method as recited in claim 8 wherein said filter is further configured to perform:
$$y [ k ] = \{ \frac{1}{4} \cdot x [ n ] - \frac{1}{4} \cdot x [ n - 1 ] - \frac{1}{4} \cdot x [ n - 2 ] + \frac{1}{4} \cdot x [ n - 3 ] \} \cdot {μ}^{2} + \{ - \frac{1}{4} \cdot x [ n ] + \frac{5}{4} x [ n - 1 ] - \frac{3}{4} \cdot x [ n - 2 ] - \frac{1}{4} \cdot x [ n - 3 ] \} \cdot μ + x [ n - 2 ] .$$

13. The method as recited in claim 8 wherein said first sampling rate and said second sampling rate are not related by an integer multiple.

14. The method as recited in claim 8 wherein said method is carried out in a wireless transmitter selected from the group consisting of:
a polar transmitter, and
a Cartesian transmitter.

15. A wireless transmitter, comprising:
a digital baseband unit;
a pulse-shaping filter coupled to the digital baseband unit and configured to operate in a first clock domain to provide digital data sampled at a first sampling rate;
a sample rate converter coupled to said pulse-shaping filter and responsive to an interpolating signal to apply coefficients having only one nonunitary divisor to said digital data from said first clock domain; and
an output coupled to said sample rate converter and configured to provide digital data to a second clock domain sampled at a second sampling rate that differs from said first sampling rate.

16. The wireless transmitter as recited in claim 15 further comprising a single clock source configured to establish said first sampling rate and said second sampling rate.

17. The wireless transmitter as recited in claim 15 wherein said first sampling rate is less than said second sampling rate.

18. The wireless transmitter as recited in claim 15 wherein said first sampling rate and said second sampling rate are not related by an integer multiple.

19. The wireless transmitter as recited in claim 15 wherein said wireless transmitter is selected from the group consisting of:
a polar transmitter, and
a Cartesian transmitter.

20. The wireless transmitter as recited in claim 15 wherein the sample rate converter is a filter with a second-order, polynomial-based impulse response.

21. The wireless transmitter as recited in claim 16 wherein said first sampling rate and said second sampling rate are established through frequency division of said single clock source.

22. The wireless transmitter as recited in claim 21 wherein said interpolating signal is generated through said frequency division.
